(19) United States
(12) Patent Application Publication
(10) Pub. No.: US 2025/0201657 A1
(43) Pub. Date: Jun. 19, 2025

(54) HYBRID THERMAL INTERFACE MATERIAL WITH EMBEDDED METAL LAYER

(71) Applicant: Sandisk Technologies, Inc., Milpitas, CA (US)

(72) Inventors: Uthayarajan A/L Rasalingam, Penang (MY); Bharath Radhakrishnan, Penang (MY)

(21) Appl. No.: 18/545,601

(22) Filed: Dec. 19, 2023

(51) Int. Cl. H01L 23/373; H01L 23/00

(52) U.S. Cl. CPC H01L 23/3735; H01L 24/16; H01L 2224/16225; H01L 2924/1433

(57) ABSTRACT

A thermal interface material for a semiconductor package includes three separate layers or portions—a first layer, a second layer and a metal layer. The metal layer is provided between the first layer and the second layer. The second layer defines a plurality of apertures and the metal layer defines a plurality of stubs. The first layer, the second layer and the metal layer are combined to form the thermal interface material. During formation, the plurality of stubs are at least partially received within respective apertures of the plurality of apertures defined by the second layer. When the thermal interface material is placed on an integrated circuit of the semiconductor package, the stubs contact the top surface of the integrated circuit to dissipate heat.

### BACKGROUND

Semiconductor packages typically include a number of different semiconductor chips that process and store data. For example, a semiconductor package can include one or more integrated circuits and one or more memory dies. As demand for semiconductor packages increases, so do the demands for higher density, smaller size and higher performance. However, higher performance typically means faster integrated circuits and memory dies. As these components get faster, they consume more power and, as a result, generate more heat.

Typically, the generated heat is dissipated using a thermal interface material. For example, the thermal interface material is placed or provided on a top surface of the integrated circuit or the one or more memory dies. The thermal interface material transfers heat from the integrated circuit or the one or more memory dies to a housing or heat sink of the semiconductor package.

However, current thermal interface materials are not very efficient and do not provide optimal heat transfer. For example, the volume resistivity and thermal conductivity between the integrated circuit and the thermal interface material is not optimized. Additionally, during installation of the thermal interface material on the integrated circuit, air gaps can form between the surface of the of the integrated circuit and the thermal interface material and/or the thermal interface material is not evenly installed (e.g., uneven quantities are provided one some surface areas of the integrated circuit when compared to other areas). These issues lead to inconsistent heat transfer and instability and negatively impact the performance of the semiconductor package.

Accordingly, it would be beneficial for a thermal interface material to have thermal dissipation features that effectively and efficiently dissipate heat from the integrated circuit and/or the one or more memory dies of a semiconductor package and address the other drawbacks outlined above.

### SUMMARY

The present disclosure describes a thermal interface material (also referred to as a “thermal interface layer”) for a semiconductor package. In an example, the thermal interface material includes three separate layers or portions—a first layer, a second layer and a metal layer provided between the first layer and the second layer. In an example, the second layer defines a plurality of apertures and the metal layer includes or defines a plurality of posts or stubs. The first layer, the second layer and the metal layer are combined to form the thermal interface material. During formation, the plurality of posts or stubs are at least partially received within respective apertures of the plurality of apertures defined by the second layer.

Once formed, the thermal interface material is provided on a top surface of an integrated circuit of the semiconductor package. The addition of the metal layer within the thermal interface material improves the strength of the thermal interface material and also improves the heat dissipation properties of the thermal interface material when compared with current solutions.

Accordingly, examples of the present disclosure describe a thermal interface material for an integrated circuit. In an example, the thermal interface material includes a first portion and a second portion. The second portion is separate from the first portion and defines a plurality of apertures. The thermal interface material also includes a metal portion provided between the first portion and the second portion. In an example, the metal portion includes a plurality of stubs that are received into respective apertures of the plurality of apertures defined by the second portion.

Other examples describe a semiconductor package that includes a substrate, an integrated circuit electrically coupled to the substrate and a housing at least partially covering the integrated circuit. The semiconductor package also includes a thermal interface material provided between the integrated circuit and the housing. The thermal interface material includes a first layer and a second layer. In an example, the second layer defines at least one cavity. The thermal interface material also includes a metal layer positioned between the first layer and the second layer. The metal layer includes at least one post that is at least partially received in the at least one cavity defined by the second layer.

Examples also describe a semiconductor package that includes a substrate, an integrated circuit means electrically coupled to the substrate and a housing means at least partially covering the integrated circuit means. The semiconductor package also includes a thermal dissipation means provided between the integrated circuit means and the housing means. In an example, the thermal dissipation means includes a first layer and a second layer. The second layer defines a plurality of apertures. The thermal dissipation means also includes a metal layer provided between the first layer and the second layer. In an example, the metal layer includes a plurality of heat dissipation means that are received in respective apertures of the plurality of apertures defined by the second layer.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a semiconductor package having a thermal interface material according to current solutions.

FIG. 2A illustrates an exploded view of a thermal interface material according to an example.

FIG. 2B illustrates the thermal interface material of FIG. 2A in an assembled configuration according to an example.

FIG. 3 illustrates an exploded isometric view of a thermal interface material according to an example.

FIG. 4 illustrates a semiconductor package having a thermal interface material according to an example.

FIG. 5 illustrates a method for manufacturing a thermal interface material according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As previously explained, a semiconductor package typically includes various electronic components including integrated circuits and/or one or more memory dies. As these electronic components operate, they consume power and generate heat. The heat is dissipated using a thermal interface material. For example, the thermal interface material is placed between a top surface of the integrated circuit and a housing or a heat sink of the semiconductor package. As heat is generated, the thermal interface material transfers heat from the integrated circuit to the housing.

However, current thermal interface materials do not provide optimal heat transfer. This is due to a number of factors. For example, there is no optimized volume resistivity and/or thermal conductivity between the integrated circuit and the thermal interface material. Additionally, air gaps can form between the surface of the of the integrated circuit and the thermal interface material during installation and/or it is difficult to evenly install the thermal interface material. For example, during installation, uneven quantities of the thermal interface material may be provided one some surface areas of the integrated circuit when compared to other areas. These issues lead to inconsistent heat transfer and instability and negatively impact the performance of the semiconductor package.

In order to address the above, the present disclosure describes a thermal interface material for a semiconductor package. In an example, the thermal interface material includes three separate portions or layers. For example, the thermal interface material includes a first portion, a second portion and a metal portion. The metal portion is provided between the first portion and the second portion. In an example, the second portion defines a plurality of apertures and the metal portion defines a plurality of posts or stubs. The first portion, the second portion and the metal portion are combined to form the thermal interface material. During formation, the plurality of posts or stubs are at least partially received within respective apertures of the plurality of apertures defined by the second portion.

Once formed, the thermal interface material is provided on a top surface of an integrated circuit of the semiconductor package. The addition of the metal portion within the thermal interface material improves the strength of the thermal interface material and also improves the heat dissipation properties of the thermal interface material when compared with current solutions.

Accordingly, many technical benefits may be realized including, but not limited to, increasing the reliability of the thermal interface material as the addition of a metal sheet improves the overall strength of the thermal interface material, improving heat dissipation properties of the thermal interface material due to the addition of the embedded metal sheet which has a higher conductivity rate when compared with current solutions and the surface area of the thermal interface material can be reduced while still improving the heat dissipation properties of the thermal interface material when compared with current solutions. As such, the thermal interface material may be targeted for areas on the integrated circuit that typically generate more heat (e.g., the center of the integrated circuit versus an outer perimeter of the integrated circuit.

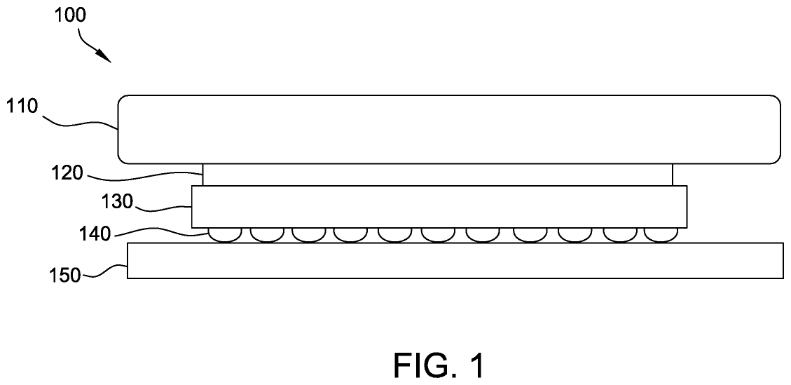

These benefits, along with other examples, will be shown and described in greater detail with respect to FIG. 1-FIG. 5.

FIG. 1 is a semiconductor package 100 having a thermal interface material 120 according to current solutions. In the example shown, the semiconductor package 100 includes an integrated circuit 130. The integrated circuit 130 is coupled to a substrate 150 using one or more solder balls 140 or other connection mechanisms.

The semiconductor package 100 also includes a housing (or a heat sink) 110. In some implementations, the housing 110 partially covers the integrated circuit 130. In other implementations, the housing 110 completely encloses the integrated circuit 130.

As briefly explained, the semiconductor package 100 also includes a thermal interface material 120. The thermal interface material 120 is provided between the integrated circuit 130 and the heat sink 110. However, as previously explained, the thermal interface material 120 is not optimized with respect to volume resistivity and/or thermal conductivity. Additionally, when the thermal interface material is installed on the integrated circuit 130, air gaps can form between the surface of the of the integrated circuit 130 and the thermal interface material 120. The air gaps reduce the heat transfer properties and effectiveness of the thermal interface material 120.

In some implementations, the thermal interface material 120 is dispensed in a liquid form. As a result, uneven quantities of the thermal interface material 120 may be provided on some surface areas of the integrated circuit 120 when compared to other areas. As a result, some areas of the integrated circuit 130 and/or the housing 110 are in contact with the thermal interface material 120 while other areas are not. In other examples, when the thermal interface material 120 is dispensed, some of the thermal interface material may spill over the edge of the integrated circuit 130. These issues lead to inconsistent heat transfer and instability and negatively impact the performance of the semiconductor package 100.

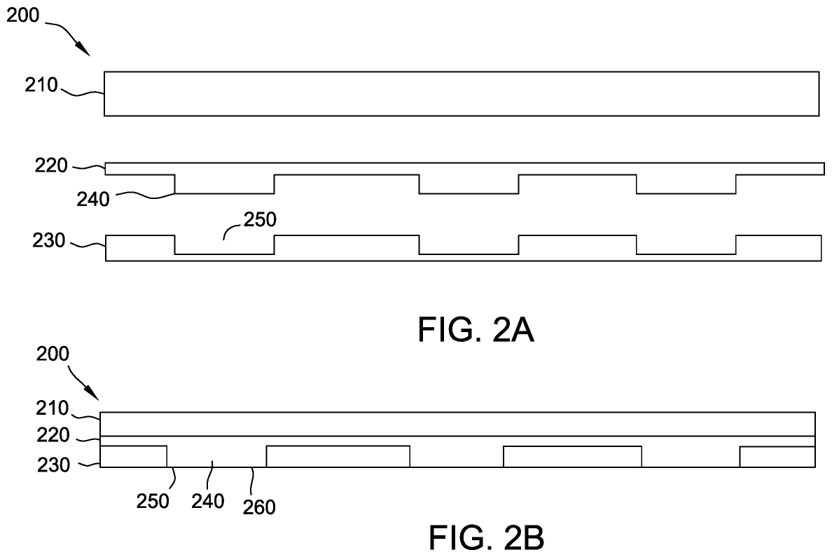

FIG. 2A illustrates an exploded view of a thermal interface material 200 according to an example. In an example, the thermal interface material 200 includes at least three separate layers or portions. For example, the thermal interface material 200 includes a first layer 210 or portion, a second layer 230 or portion and a middle layer 220 or portion.

The first layer 210 and/or the second layer 230 include one or more materials that have thermal conductivity properties and/or electrical insulation properties. For example, the first layer 210 and/or the second layer 230 may be comprised of silicone, an adhesive tape, grease, phase change materials or any other material having thermal conductivity properties and/or electrical insulation properties.

In an example, the middle layer 220 is a metal layer, such as, for example, a copper layer (e.g., copper foil). Although copper is specifically mentioned, other metals/materials may be used. The middle layer 220 also includes or otherwise defines, one or more stubs 240 or posts. Each stub 240 is formed in/from the middle layer 220 extends from a bottom surface of the middle layer 220.

In an example, each of the stubs 240 are formed during a manufacturing process. For example, a stamping process may be used to form each stub 240 on/in the middle layer 220. Once formed, the stubs 240 may be filled with a material. In one example, each stub 240 is filled with a conductive material such as copper. In another example, each stub 240 is filled with the same (or similar material) that is used to create the first layer 210 and/or the second layer 230. In yet another example, each stub 240 may be hollow.

Each stub 240 is shaped and/or sized to be received into corresponding apertures 250 or cavities that are formed in, or are otherwise defined by, the second layer 230. For example, when the second layer 230 is formed, a mold may be used to define or otherwise form the apertures 250 in the second layer 230. In an example, a depth of the apertures 250 is equivalent to a height of the second layer 230. As such, the apertures 250 extend completely through the second layer 230. In another example, the apertures 250 have a depth that causes the apertures 250 to extend at least partially though the second layer 230.

When the apertures 250 are formed in or are otherwise defined by the second layer 230, the stubs 240 of the middle layer 220 are received into the apertures 250. In an example, the stubs 240 have a height that is equivalent to (or is substantially equivalent to) a depth of the apertures 250. As such, the stubs 240 extend from the bottom surface of the middle layer 220 and at least partially contact a top surface of an integrated circuit or memory die (e.g., a NAND die) on which the thermal interface material 200 is placed.

In an example, each of the first layer 210, the second layer 230 and the middle layer 220 are manufactured separately. Once manufactured, each of the layers are compressed to form a single structure. The structure may then be placed on the top surface of the integrated circuit or a memory die. In another example, each portion of the thermal interface material 200 is individually placed on the top surface of the integrated circuit or the memory die and compressed (e.g., when a housing is placed on the thermal interface material 200 and integrated circuit).

For example, the second layer 230 is placed on the top surface of the integrated circuit, followed by the middle layer 220. During this assembly phase, the stubs 240 of the middle layer 220 are received into corresponding apertures 230 of the second layer 230. The first layer 210 is then placed on the top surface of the middle layer 220.

Although FIG. 2A shows stubs 240 extending from the bottom surface of the middle layer 220, stubs 240 may also extend from a top surface of the middle layer 220. In such examples, the stubs 240 extend into one or more apertures defined by the first layer 210. Additionally, the stubs 240 that extend from the top surface of the middle layer may at least partially contact a bottom surface of a housing of a semiconductor package.

FIG. 2B illustrates the thermal interface material 200 of FIG. 2A in an assembled configuration according to an example. As shown in FIG. 2B, when the thermal interface material 200 is assembled, the stubs 240 of the middle layer 220 are received into corresponding apertures 250 defined by the second layer 230. In an example, a bottom surface 260 of at least one of the stubs 240 extends through the second layer 220 such that at least a portion of the bottom surface of the at least one stub 240 will at least partially contact a top surface of an integrated circuit or memory die on which the thermal interface material 200 is placed.

In an example, each of the first layer 210, the second layer 230 and the middle layer 220 have a thickness. For example, the first layer 210 has a first thickness, the second layer 230 has a second thickness and the middle layer 220 has a third thickness. In an example, the second thickness is less than the first thickness and the third thickness is less than the second thickness. In some examples, the second layer 230 is half as thick as the first layer 210 and the middle layer is half as thick as the second layer 230. However, as previously discussed, a thickness of the stubs 240 may be equivalent or substantially equivalent to a thickness of the second layer 230.

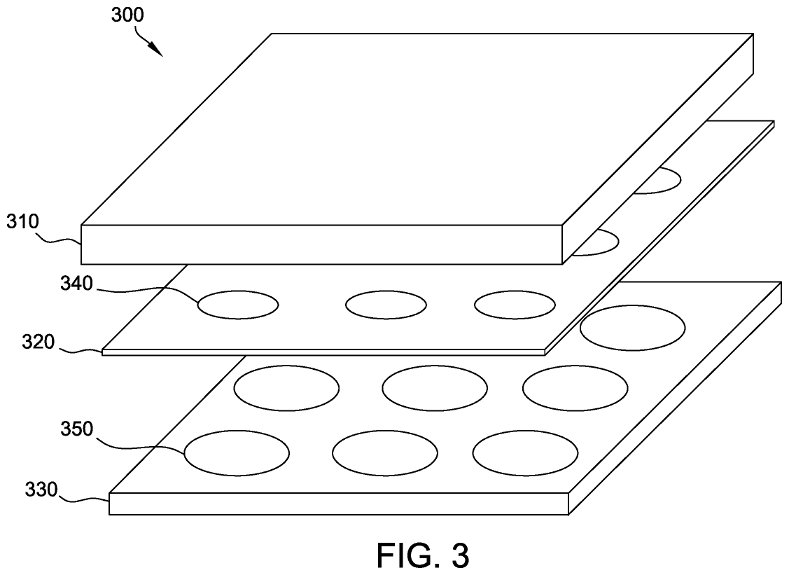

FIG. 3 illustrates an exploded isometric view of a thermal interface material 300 according to an example. In an example, the thermal interface material 300 is similar to the thermal interface material 200 shown and described with respect to FIG. 2A-FIG. 2B.

In an example, the thermal interface material 300 includes three separate layers—a first layer 310, a second layer 330 and a metal layer 320 (or a middle layer). As previously discussed, in an example, the metal layer 320 is a copper foil layer.

The first layer 310 has a first thickness, the second layer 330 has a second thickness that is less than the first thickness and the metal layer 320 has a third thickness that is less than the second thickness. In an example, the second layer 330 is half as thick as the first layer 310 and the metal layer 320 is half as thick as the second layer 330.

The metal layer 320 includes a plurality of stubs 340 or posts that extend from a bottom surface of the metal layer 320. In an example, the metal layer 320 may also include a plurality of posts or stubs that extend from a top surface of the metal layer. The plurality of stubs 340 may be arranged in various rows and columns.

The second layer 330 defines a plurality of apertures 250 or cavities. In an example, the plurality of apertures 250 are arranged in various rows and columns and receive corresponding stubs 240 when the thermal interface material 300 is compressed or otherwise formed into a single unit. In an example, the apertures 250 extend though the second layer 330. As such, when the metal layer 320 is placed on a top surface of the second layer 330 and the stubs 340 are received into corresponding apertures 350, a bottom surface of the stubs 340 contact a top surface of the integrated circuit or memory die on which the thermal interface material is placed.

In the example shown in FIG. 3, the stubs 340 and the apertures 350 are circular or have a round shape. Although a round shape is shown and described, the stubs 340 and the apertures 350 may have any shape.

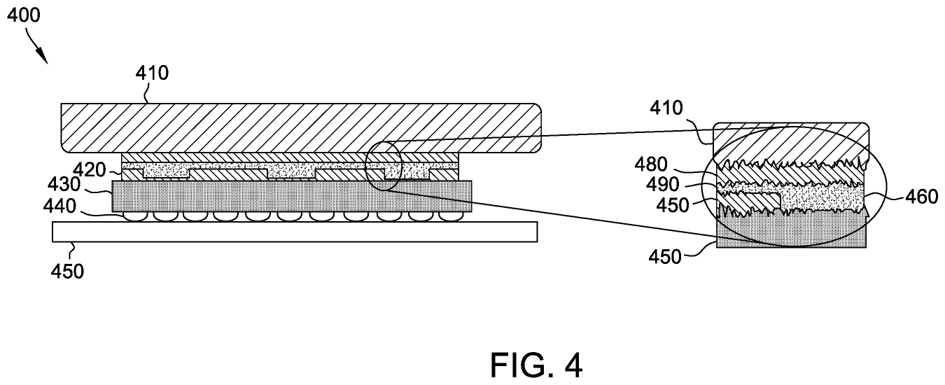

FIG. 4 illustrates a semiconductor package 400 having a thermal interface material 420 according to an example. In an example, the thermal interface material 420 is similar to the thermal interface material 200 shown and described with respect to FIG. 2A-FIG. 2B and the thermal interface material 300 shown and described with respect to FIG. 3.

In an example, the semiconductor package 400 includes an integrated circuit 430. The integrated circuit 430 may be any application specific integrated circuit (ASIC). In another example, the integrated circuit 430 is a memory die such as, for example a NAND memory die (or a stack of NAND memory dies). The integrated circuit 430 is coupled to a substrate 450 using one or more solder balls 440 or other connection mechanisms.

The semiconductor package 400 also includes a housing 110. The housing 110 may be a heat sink or other covering that at least partially covers or encloses the integrated circuit 430.

As briefly explained, the semiconductor package 400 also includes a thermal interface material 420. The thermal interface material 420 is provided or sandwiched between the integrated circuit 430 and the housing 410. In an example, at least a portion of the top surface of the thermal interface material 420 contacts a bottom surface of the housing 410. Additionally, at least a portion of a bottom surface of the thermal interface material 420 contacts a top surface of the integrated circuit 430.

Specifically, and as shown in the call-out portion of FIG. 4, a top surface of a first portion 480 of the thermal interface material 420 contacts a bottom surface of the housing 410. Additionally, one or more stubs 460 extend from a bottom surface of a metal layer 490 of the thermal interface material 420 and are received into one or more apertures of a second layer 470 of the thermal interface material 420. In an example, at least a portion of the bottom surface of the stub 460 contacts at least a portion of a top surface of the integrated circuit 450.

Because the copper/metal stub 460 is in direct contact with the integrated circuit 450, thermal conductivity and heat dissipation is improved when compared with the thermal interface material 120 shown and described with respect to FIG. 1. Specifically, the high conductivity of the metal layer 490 enables faster and more efficient heat dissipation from the integrated circuit 450. For example, heat is transferred from the integrated circuit 450 to/through the stub 460 which then transfers heat through the metal layer 490. The metal layer 490 then transfers the heat to the first layer 480 which transfers the heat to the housing 410. Additionally, the metal layer 490 provides strength to, and increases the durability of, the thermal interface material 420—especially when compared to the thermal interface material 120 shown and described with respect to FIG. 1.

In an example, the thermal interface material 420 is manufactured or formed as a single unit prior to being placed on the top surface of the integrated circuit 430. In another example, each portion of the thermal interface material 420 may be placed on the integrated circuit and subsequently compressed as previously discussed.

In an example, the dimensions and/or size of the thermal interface material 420 is configured based, at least in part, on the dimensions and/or size of the integrated circuit 430. In another example, the size and/or dimensions of the thermal interface material 420 is configured such that hotter areas (e.g., a middle portion) of the integrated circuit 430 has more/bigger stubs 460 when compared with areas that are less hot (e.g., outer edges of the integrated circuit 430). In yet another example, the dimensions and/or size of the thermal interface material 420 is the same, or substantially the same, as the dimensions and/or size of the integrated circuit 430. In other examples, the dimensions and/or size of the thermal interface material 420 is larger or smaller than the dimensions and/or size of the integrated circuit 430.

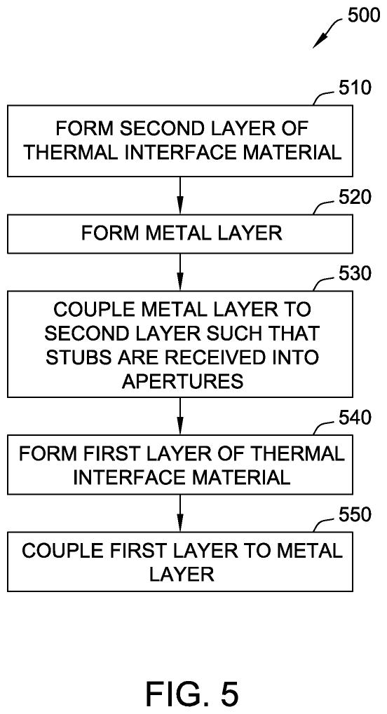

FIG. 5 illustrates a method 500 for manufacturing a thermal interface material according to an example. In an example, the method 500 may be used to manufacture or create the thermal interface material 200 shown and described with respect to FIG. 2B and/or the thermal interface material 420 shown and described with respect to FIG. 4.

Method 500 begins when a second layer of the thermal interface material is formed (510). In an example, the second layer is similar to the second layer 330 shown and described with respect to FIG. 3. As such, one or more apertures or cavities are formed in, or are otherwise defined by, the second layer. Additionally, the second layer has a thickness. In an example, the thickness of the second layer is less than a thickness of a first layer that will be formed (or has been formed) as part of the method 500.

The method 500 also includes the formation (520) of a metal layer. In an example, the metal layer is comprised of copper foil. Although copper foil is specifically mentioned, other materials/metals may be used. For example, the metal layer may be any type of material with high properties of conductivity scale or low resistivity scale. of As part of the formation process, one or more stubs are formed in or on the copper foil. For example, during manufacturing, a stamp or press may be used to form one or more stubs in the copper foil. Additionally, the stubs may be solid or hollow. The metal layer has a thickness. In an example, the thickness of the metal layer is less than the thickness of the second layer. However, in an example a thickness or a height of the stub is equivalent to the thickness of the second layer.

The metal layer is then coupled (530) to the second layer such that the stubs are received into corresponding apertures defined by the second layer. In an example, when the stubs are received into the various apertures, a bottom surface of each stub is exposed with respect to a bottom surface of the second layer.

A first layer of the thermal interface material is then formed (540) and coupled to the metal layer (550). Once the first layer, the second layer and the metal layer have been formed and/or coupled together, the various portions are compressed to form a single unit of a thermal interface material.

In an example, the method 500 may be used to produce or manufacture a thermal interface material that may subsequently be placed on an integrated circuit. In another example, each component or portion may be manufactured separately. In this example, each individual piece is placed on the integrated circuit. For example, the second layer is placed on the integrated circuit, followed by the metal layer, followed by the first layer.

Based on the above, examples of the present disclosure describe a thermal interface material for an integrated circuit, comprising: a first portion; a second portion separate from the first portion and defining a plurality of apertures; and a metal portion provided between the first portion and the second portion, the metal portion including a plurality of stubs that are received in respective apertures of the plurality of apertures defined by the second portion. In an example, the metal portion is comprised of a copper foil. In an example, at least one stub of the plurality of stubs is filled with a copper material. In an example, the first portion has a first thickness, the second portion has a second thickness that is less than the first thickness and the metal portion has a third thickness that is less than the second thickness. In an example, the second thickness is half as thick as the first thickness and the third thickness is half as thick as the second thickness. In an example, at least a portion of one or more of the plurality of stubs contacts a surface of the integrated circuit when the thermal interface material is coupled to the integrated circuit. In an example, the first portion, the second portion and the metal portion are compressed to form a single unit prior to being placed on a surface of the integrated circuit.

Examples also describe a semiconductor package, comprising: a substrate; an integrated circuit electrically coupled to the substrate; a housing at least partially covering the integrated circuit; and a thermal interface material provided between the integrated circuit and the housing, the thermal interface material comprising: a first layer; a second layer, the second layer defining at least one cavity; and a metal layer positioned between the first layer and the second layer, the metal layer including at least one post that is at least partially received in the at least one cavity. In an example, the metal layer is comprised of copper. In an example, the at least one post is filled with copper. In an example, the first layer has a first thickness, the second layer has a second thickness that is less than the first thickness and the metal layer has a third thickness that is less than the second thickness. In an example, the second thickness is half as thick as the first thickness and the third thickness is half as thick as the second thickness. In an example, at least a portion of the at least one post contacts a surface of the integrated circuit when the thermal interface material is placed on a surface of the integrated circuit. In an example, the first layer, the second layer and the metal layer are compressed to form a single unit prior to being placed on a surface of the integrated circuit.

Other examples describe a semiconductor package, comprising: a substrate; an integrated circuit means electrically coupled to the substrate; a housing means at least partially covering the integrated circuit means; and a thermal dissipation means provided between the integrated circuit means and the housing means, the thermal interface means comprising: a first layer; a second layer defining a plurality of apertures; and a metal layer provided between the first layer and the second layer, the metal layer including a plurality of heat dissipation means that are received in respective apertures of the plurality of apertures. In an example, the metal layer is comprised of copper. In an example, the plurality of heat dissipation means are filled with copper. In an example, the first layer has a first thickness, the second layer has a second thickness that is less than the first thickness and the metal layer has a third thickness that is less than the second thickness. In an example, the second thickness is half as thick as the first thickness and the third thickness is half as thick as the second thickness. In an example, the first layer, the second layer and the metal layer are compressed to form a single unit.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to a block diagram of a method. It will be understood that each block or combinations of blocks in the block diagram may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A thermal interface material for an integrated circuit, comprising:
a first portion;
a second portion separate from the first portion and defining a plurality of apertures; and
a metal portion provided between the first portion and the second portion, the metal portion including a plurality of stubs that are received in respective apertures of the plurality of apertures defined by the second portion.

2. The thermal interface material of claim 1, wherein the metal portion is comprised of a copper foil.

3. The thermal interface material of claim 1, wherein at least one stub of the plurality of stubs is filled with a copper material.

4. The thermal interface material of claim 1, wherein the first portion has a first thickness, the second portion has a second thickness that is less than the first thickness and the metal portion has a third thickness that is less than the second thickness.

5. The thermal interface material of claim 4, wherein the second thickness is half as thick as the first thickness and the third thickness is half as thick as the second thickness.

6. The thermal interface material of claim 1, wherein at least a portion of one or more of the plurality of stubs contacts a surface of the integrated circuit when the thermal interface material is coupled to the integrated circuit.

7. The thermal interface material of claim 1, wherein the first portion, the second portion and the metal portion are compressed to form a single unit prior to being placed on a surface of the integrated circuit.

8. A semiconductor package, comprising:
a substrate;
an integrated circuit electrically coupled to the substrate;
a housing at least partially covering the integrated circuit; and
a thermal interface material provided between the integrated circuit and the housing, the thermal interface material comprising:
a first layer;
a second layer, the second layer defining at least one cavity; and
a metal layer positioned between the first layer and the second layer, the metal layer including at least one post that is at least partially received in the at least one cavity.

9. The semiconductor package of claim 8, wherein the metal layer is comprised of copper.

10. The semiconductor package of claim 8, wherein the at least one post is filled with copper.

11. The semiconductor package of claim 8, wherein the first layer has a first thickness, the second layer has a second thickness that is less than the first thickness and the metal layer has a third thickness that is less than the second thickness.

12. The semiconductor package of claim 11, wherein the second thickness is half as thick as the first thickness and the third thickness is half as thick as the second thickness.

13. The semiconductor package of claim 8, wherein at least a portion of the at least one post contacts a surface of the integrated circuit when the thermal interface material is placed on a surface of the integrated circuit.

14. The semiconductor package of claim 8, wherein the first layer, the second layer and the metal layer are compressed to form a single unit prior to being placed on a surface of the integrated circuit.

15. A semiconductor package, comprising:
a substrate;
an integrated circuit means electrically coupled to the substrate;
a housing means at least partially covering the integrated circuit means; and
a thermal dissipation means provided between the integrated circuit means and the housing means, the thermal interface means comprising:
a first layer;
a second layer defining a plurality of apertures; and
a metal layer provided between the first layer and the second layer, the metal layer including a plurality of heat dissipation means that are received in respective apertures of the plurality of apertures.

16. The semiconductor package of claim 15, wherein the metal layer is comprised of copper.

17. The semiconductor package of claim 15, wherein the plurality of heat dissipation means are filled with copper.

18. The semiconductor package of claim 15, wherein the first layer has a first thickness, the second layer has a second thickness that is less than the first thickness and the metal layer has a third thickness that is less than the second thickness.

19. The semiconductor package of claim 18, wherein the second thickness is half as thick as the first thickness and the third thickness is half as thick as the second thickness.

20. The semiconductor package of claim 15, wherein the first layer, the second layer and the metal layer are compressed to form a single unit.
